(19) United States
(12) Patent Application Publication
(10) Pub. No.: US 2026/0058651 A1
(43) Pub. Date: Feb. 26, 2026

(54) GATE DRIVE CIRCUIT

(71) Applicant: FUJI ELECTRIC CO., LTD., Kawasaki-shi (JP)

(72) Inventor: Hidetomo OHASHI, Matsumoto-city (JP)

(73) Assignee: FUJI ELECTRIC CO., LTD., Kawasaki-shi (JP)

(21) Appl. No.: 19/247,689

(22) Filed: Jun. 24, 2025

(30) Foreign Application Priority Data
Aug. 26, 2024 (JP) 2024-144109

(51) Int. Cl. H03K 17/284

(52) U.S. Cl. CPC H03K 17/284

(57) ABSTRACT

A gate drive circuit includes a signal line, a first switching element, a second switching element, a first diode, a second diode, a capacitor, a third switching element, a control unit, and a delay circuit. The signal line is connected to a gate terminal of a voltage-control switching element. The first switching element is connected between a positive electrode of a direct-current power supply and the signal line. The second switching element is connected between a negative electrode of the direct-current power supply and the signal line. The delay circuit is configured to delay rising of a signal to be input into the gate terminal of the second switching element.

### CROSS-REFERENCE TO RELATED APPLICATION

This application claims benefit of priority under 35 USC 119 based on Japanese Patent Application No. 2024-144109, filed on Aug. 26, 2024, the entire contents of which are incorporated by reference herein.

### BACKGROUND OF THE INVENTION

### 1. Field of the Invention

The present disclosure relates to a gate drive circuit.

### 2. Description of the Related Art

In recent years, a HVIC (High Voltage IC) technology to achieve high-efficiency, energy saving, downsizing, and high-reliability of an Internet Data Center (IDC) power supply system such as a server or Uninterruptible Power Supply (UPS) has been developed. HVIC is a high withstand voltage gate drive circuit for driving a gate of a power device constituting a power conversion circuit (for example, JP 2015-107045 A and JP 2009-44914 A). An insulated gate bipolar transistor (IGBT) or a metal oxide semiconductor field effect transistor (MOSFET) is used as the power device. The power conversion circuit includes a series circuit of a high-side power device and a low-side power device.

In the meantime, the HVIC is constituted by a level shift circuit configured to perform level conversion of a control signal from a GND potential to a VS potential for connection to a reference potential (an emitter or a source) of the high-side power device, and a driver circuit configured to drive the power device. Note that the control signal is a control signal based on a ground (GND) potential to drive the high-side power device. A high-potential side potential of the driver circuit is connected to a positive electrode of a driving power supply. A low-potential side potential of the driver circuit is connected to a negative electrode of the driving power supply.

In the HVIC, in response to the control signal being switched from Low level to High level, a switching element on the low-potential side of the driver circuit is turned off and a switching element on the high-potential side is turned on, so that electric charges from the driving power supply are accumulated in a gate of the power device to turn on the power device. In the meantime, in the HVIC, in response to the control signal being switched from High level to Low level, the switching element on the high-potential side of the driver circuit is turned off and the switching element on the low-potential side is turned on, so that electric charges accumulated in the gate of the power device are extracted to turn off the power device.

In the meantime, at the time when the power device is turned off, electric charges accumulated in the gate of the power device transfer toward the low-potential side of the driver circuit, thereby increasing power consumption of the power conversion circuit.

Particularly, in a high frequency operation, a contribution ratio in the power consumption of the power conversion circuit increases. In view of this, the number of switching times is reduced or switching is stopped for a given period of time to take measures to reduce power consumption during standby.

In the meantime, the power conversion circuit using the power device is required to continuously stably operate for a long term and therefore has been demanded to take measures other than a reduction in the number of switching times or stopping of switching for a given period of time.

The technology described in JP 2015-107045 A is a technology to prevent flowing of a large inrush current to be caused at power-on in addition to downsizing by using a discharge resistor also as a precharge resistor of a smooth capacitor but is not a technology to restrain an increase in power consumption of the power conversion circuit. Similarly to the technology described in JP 2015-107045 A, the technology described in JP 2009-44914 A is a technology to restrain an inrush current to be caused at power-on but is not a technology to restrain an increase in power consumption of the power conversion circuit.

### SUMMARY OF THE INVENTION

In view of the foregoing problem, the present disclosure provides a gate drive circuit that can reduce power consumption of a power conversion circuit.

An aspect of the present disclosure inheres in a gate drive circuit for inputting a control signal to control a voltage-control switching element between ON state and OFF state, and for generating a driving signal to drive a voltage-control switching element based on the control signal, wherein the voltage-control switching element being configured to receive power from a direct-current power supply. The gate drive circuit includes: a signal line connected to a gate terminal of the voltage-control switching element; a first switching element connected between a positive electrode of the direct-current power supply and the signal line; a second switching element connected between a negative electrode of the direct-current power supply and the signal line; a regenerative circuit configured to accumulate electric charges in response to the voltage-control switching element being turned off, and regenerate the electric charges to the direct-current power supply, wherein the electric charges are accumulated in the gate terminal while the voltage-control switching element is turned on.

### BRIEF DESCRIPTION OF THE DRAWINGS

FIG. 1 is a block diagram illustrating an exemplary configuration of a semiconductor device provided with a gate drive circuit according to a first embodiment of the present disclosure;

FIG. 2 is a block diagram illustrating an exemplary configuration of a semiconductor device provided with a gate drive circuit in a comparative example;

FIG. 3 is a circuit diagram illustrating a configuration of a driver circuit in the comparative example;

FIG. 4 is a signal timing diagram illustrating an operation of a high-side driver circuit in the comparative example;

FIG. 5 is a circuit diagram illustrating a configuration of a driver circuit according to the first embodiment;

FIG. 6 is a circuit diagram illustrating a configuration of a regenerative circuit illustrated in FIG. 5;

FIG. 7 is a signal timing diagram illustrating an operation of a high-side driver circuit according to the first embodiment;

FIG. 8 is a circuit diagram illustrating a configuration of a driver circuit of a semiconductor device according to a second embodiment of the present disclosure; and

FIG. 9 is a signal timing diagram illustrating an operation of a high-side driver circuit according to the second embodiment.

### DETAILED DESCRIPTION

Each embodiment of the present disclosure describes a device or a method to embody the technical idea of the present disclosure, and the technical idea of the present disclosure does not specify a material, a shape, a structure, an arrangement, and the like of a component part to those described below.

Various changes can be added to the technical idea of the present disclosure within a technical scope defined by claims described in Claims.

### First Embodiment

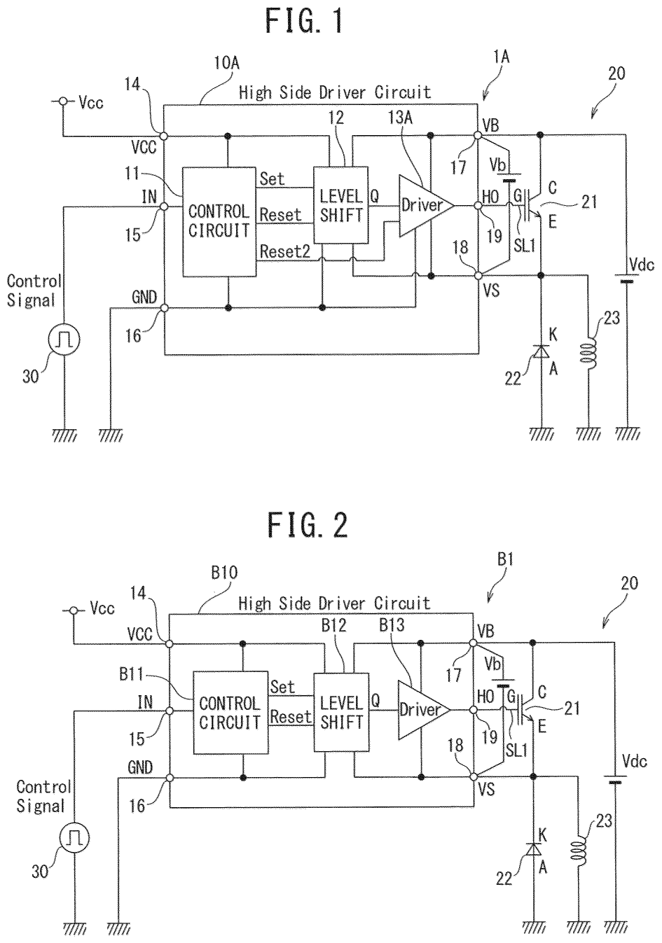

FIG. 1 is a block diagram illustrating an exemplary configuration of a semiconductor device provided with a gate drive circuit according to a first embodiment of the present disclosure.

A semiconductor device 1A includes a high-side driver circuit 10A (an example of a gate drive circuit), and a power conversion circuit 20. The power conversion circuit 20 includes a bridge-connected high-side power device 21 (an example of a voltage-control switching element), and a low-side power device (not illustrated), for example. The high-side power device 21 receives power from a direct-current power supply Vdc, and its gate terminal (G) is connected to the high-side driver circuit 10A. An insulated gate bipolar transistor (IGBT) or a metal oxide semiconductor field effect transistor (MOSFET) is used as the high-side power device 21, for example.

A positive electrode of the direct-current power supply Vdc is connected to a collector terminal (C) of the high-side power device 21. A diode 22 and an inductor 23 are connected to an emitter terminal (E) of the high-side power device 21. That is, a cathode terminal (K) of the diode 22 and one end of the inductor 23 are connected to the emitter terminal (E) of the high-side power device 21. An anode terminal (A) of the diode 22 is connected to a ground potential GND. The other end of the inductor 23 is connected to the ground potential GND.

The high-side driver circuit 10A generates a gate drive signal to drive the high-side power device 21. A control device 30 configured to control the high-side power device 21 to switch between an ON state and an OFF state is connected to the high-side driver circuit 10A via an input signal terminal 15. The high-side driver circuit 10A is connected to a ground potential GND via a GND terminal 16. A driving power supply Vb configured to drive the high-side power device 21 is connected to the high-side driver circuit 10A via a positive terminal 17 and a negative terminal 18. The high-side driver circuit 10A is configured to generate a gate drive signal by use of a control signal input from the control device 30.

The high-side driver circuit 10A includes a control circuit 11, a level shift circuit 12, and a driver circuit 13A. The control circuit 11 receives power from a main power supply Vcc via a power supply terminal 14 and has a function to generate a set pulse (Set) to turn on the high-side power device 21 in response to of rising of a control signal output from the control device 30 via the input signal terminal 15 and generate a reset pulse (Reset and Reset2) to turn off the high-side power device 21 in response to falling of the control signal.

The level shift circuit 12 has a function to shift the level of the control signal from a ground potential GND reference to a signal Q of a high-side reference potential VS in response to a set pulse and a reset pulse output from the control circuit 11. The driver circuit 13A has a function to generate a gate drive signal in response to the signal Q output from the level shift circuit 12 and output the gate drive signal to the gate terminal (G) of the high-side power device 21 via an output signal terminal 19 and a signal line SL1. The driver circuit 13 directly receives a reset pulse (Reset2) output from the control circuit 11.

### Comparative Example of First Embodiment

FIG. 2 is a block diagram illustrating an exemplary configuration of a semiconductor device provided with a gate drive circuit as a comparative example. In FIG. 2, the same portion as in FIG. 1 has the same reference sign as that of the portion in FIG. 1, and a detailed description thereof is omitted.

A semiconductor device B1 according to the comparative example includes a high-side driver circuit B10 and the power conversion circuit 20. The high-side driver circuit B10 includes a control circuit B11, a level shift circuit B12, and a driver circuit B13.

### (Configuration of Driver Circuit B13)

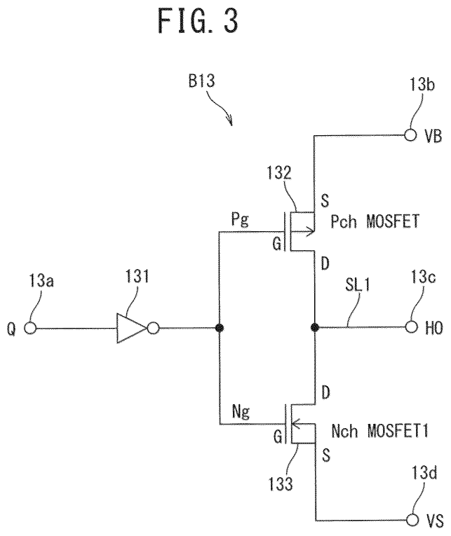

FIG. 3 is a circuit diagram illustrating a configuration of the driver circuit B13 in the comparative example. The driver circuit B13 includes a NOT circuit 131, a P-channel MOSFET 132 (an example of a first switching element), and an N-channel MOSFET 133 (an example of a second switching element). An input end of the NOT circuit 131 is connected to the level shift circuit B12 via an input signal terminal 13a. An output end of the NOT circuit 131 is connected to a gate terminal (G) of the P-channel MOSFET 132 and a gate terminal (G) of the N-channel MOSFET 133.

A source terminal(S) of the P-channel MOSFET 132 is connected to a positive electrode of a direct-current power supply Vdc and a positive electrode of the driving power supply Vb via a positive terminal 13b. A drain terminal (D) of the P-channel MOSFET 132 is connected to the gate terminal (G) of the high-side power device 21 via the signal line SL1 and an output signal terminal 13c. The drain terminal (D) of the P-channel MOSFET 132 is connected to a drain terminal (D) of the N-channel MOSFET 133. A source terminal(S) of the N-channel MOSFET 133 is connected to a negative electrode of the driving power supply Vb via a negative terminal 13d.

In a case where the voltage of a signal obtained by reversing the signal Q of the high-side reference potential VS in the NOT circuit 131 is equal to or less than a gate-source threshold voltage, the P-channel MOSFET 132 is brought into a conductive state (an ON state). When the P-channel MOSFET 132 is brought into the ON state, an output current output from the driving power supply Vb is flowed to the gate terminal (G) of the high-side power device 21, so that a gate drive signal is output to the gate terminal (G) of the high-side power device 21. In the meantime, in a case where the voltage of the signal obtained by reversing the signal Q of the high-side reference potential VS is higher than the gate-source threshold voltage, the P-channel MOSFET 132 is brought into a nonconductive state (an OFF state).

In a case where the voltage of a signal obtained by reversing the signal Q of the high-side reference potential VS in the NOT circuit 131 is equal to or more than a gate-source threshold voltage, the N-channel MOSFET 133 is brought into a conductive state (an ON state). When the N-channel MOSFET 133 is brought into the ON state, a current from the gate terminal (G) of the high-side power device 21 flows into a negative side of the driving power supply Vb, so that electric charges accumulated in the gate terminal (G) of the high-side power device 21 are extracted to turn off the high-side power device 21. In the meantime, in a case where the voltage of the signal obtained by reversing the signal Q of the high-side reference potential VS is lower than the gate-source threshold voltage, the N-channel MOSFET 133 is brought into a nonconductive state (an OFF state).

### (Operation of High-Side Driver Circuit B10)

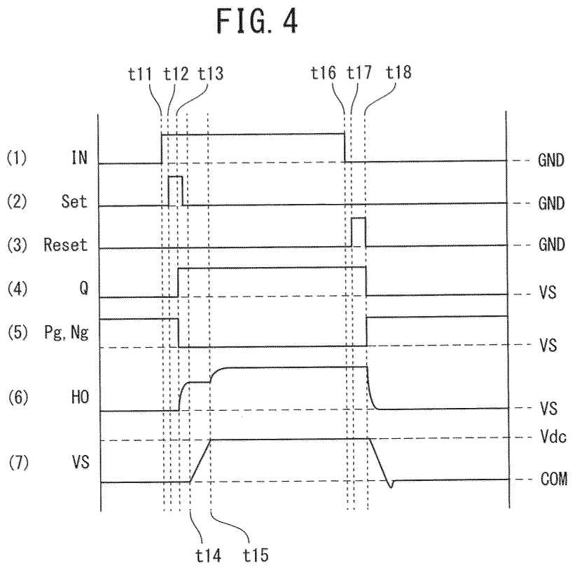

Next will be described an operation of the high-side driver circuit B10 as the comparative example with reference to FIG. 4 as well as FIGS. 2, 3.

FIG. 4 is a signal timing diagram illustrating an operation of the high-side driver circuit B10 as the comparative example. In FIG. 4, the vertical axis indicates potential, and the horizontal axis indicates time. (1) in FIG. 4 indicates the waveform of a control signal (IN) input into the input signal terminal 15 of the high-side driver circuit B10. (2) in FIG. 4 indicates the waveform of a set pulse (Set) output from the control circuit B11. (3) in FIG. 4 indicates the waveform of a reset pulse (Reset) output from the control circuit B11. (4) in FIG. 4 indicates the waveform of the signal Q of the high-side reference potential VS which signal Q is output from the level shift circuit B12. (5) in FIG. 4 indicates the waveform of a signal Pg input into the gate terminal (G) of the P-channel MOSFET 132 and a signal Ng input into the gate terminal (G) of the N-channel MOSFET 133. (6) in FIG. 4 indicates the waveform of a voltage HO of the gate terminal (G) of the high-side power device 21. (7) in FIG. 4 indicates the waveform of the high-side reference potential VS of the high-side power device 21.

In the high-side driver circuit B10, in response to the control signal (IN) input into the input signal terminal 15 being switched from Low level to High level as indicated by (1) in FIG. 4 (time t11), the control circuit B11 outputs a set pulse (Set) to the level shift circuit B12 (time t12) The set pulse (Set) is indicated by (2) in FIG. 4.

Upon receipt of the set pulse (Set), the level shift circuit B12 switches the signal Q of the high-side reference potential VS from Low level to High level to output the driver circuit B13, as indicated by (4) in FIG. 4 (time t13). In the driver circuit B13, the NOT circuit 131 reverses the signal Q of the high-side reference potential VS, outputs a signal (Pg) to the gate terminal (G) of the P-channel MOSFET 132, and outputs a signal (Ng) to the gate terminal (G) of the N-channel MOSFET 133, as indicated by (5) in FIG. 4.

When the P-channel MOSFET 132 is brought into the ON state and the N-channel MOSFET 133 is brought into the OFF state at time t13, a current output from the driving power supply Vb flows through the positive terminal 13b and the source terminal(S) and the drain terminal (D) of the P-channel MOSFET 132 and flows into a gate-emitter capacitance (not illustrated) formed between the gate terminal (G) and the emitter terminal (E) of the high-side power device 21. Hereby, the gate-emitter capacitance of the high-side power device 21 is charged, so that the voltage (the gate voltage HO) of the gate terminal (G) of the high-side power device 21 increases.

As a result, as indicated by (6) in FIG. 4, the gate voltage HO of the high-side power device 21 becomes higher than the high-side reference potential VS of the high-side power device 21 at time t14 when a predetermined time elapses from time t13. After a mirror period (from time t14 to time t15), the gate voltage HO of the high-side power device 21 rises to a voltage value that can maintain the high-side power device 21 in the ON state (time t15). The mirror period corresponds to a predetermined time that elapses from time t14. That is, the high-side power device 21 is turned on.

In response to the high-side power device 21 being brought into the ON state, the high-side reference potential VS of the high-side power device 21 gradually rises from a potential COM of the diode 22 and the inductor 23 to a potential of the direct-current power supply Vdc (from time t14 to time t15). The high-side reference potential VS is indicated by (7) in FIG. 4.

In the meantime, in response to the control signal (IN) input into the input signal terminal 15 being switched from High level to Low level as indicated by (1) in FIG. 4 (time t16), the control circuit B11 outputs a reset pulse (Reset) to the level shift circuit B12 (time t17). The reset pulse (Reset) is indicated by (3) in FIG. 4.

Upon receipt of the reset pulse (Reset), the level shift circuit B12 switches the signal Q of the high-side reference potential VS from High level to Low level to output to the driver circuit B13 as indicated by (4) in FIG. 4 (time t18).

When the P-channel MOSFET 132 is brought into the OFF state and the N-channel MOSFET 133 is brought into the ON state at time t18, the voltage level of the gate drive signal output from the output signal terminal 13c is Low level. Accordingly, electric charges accumulated in the gate-emitter capacitance of the high-side power device 21 flow to the N-channel MOSFET 133 via the output signal terminal 13c and the signal line SL1, so that the gate-emitter capacitance of the high-side power device 21 is discharged. As a result, the gate voltage HO of the high-side power device 21 decreases as indicated by (6) in FIG. 4. That is, the high-side power device 21 is turned off.

In response to the high-side power device 21 being brought into the OFF state, the high-side reference potential VS of the high-side power device 21 gradually falls from the potential of the direct-current power supply Vdc to the potential COM of the diode 22 and the inductor 23. The high-side reference potential VS is indicated by (7) in FIG. 4.

In the meantime, in the comparative example, at the time of turning off the high-side power device 21, electric charges accumulated in the gate terminal (G) of the high-side power device 21 are consumed as Joule heat in the N-channel MOSFET 133 of the driver circuit B13, thereby resulting in that power consumption of the power conversion circuit 20 increases.

### Implementation Means by First Embodiment

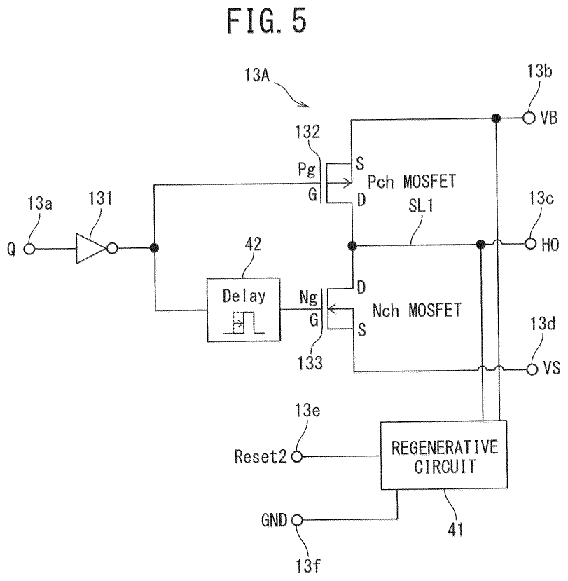

FIG. 5 is a circuit diagram illustrating a configuration of the driver circuit 13A according to the first embodiment. In FIG. 5, the same portion as in FIG. 3 has the same reference sign as that of the portion in FIG. 3, and a detailed description thereof is omitted.

The driver circuit 13A includes the NOT circuit 131, the P-channel MOSFET 132 (an example of the first switching element), the N-channel MOSFET 133 (an example of the second switching element), a regenerative circuit 41, and a delay circuit 42. The regenerative circuit 41 is connected to the positive electrode of the driving power supply Vb, that is, the positive terminal 13b and the signal line SL1. The regenerative circuit 41 is provided with an input signal terminal 13e and a GND terminal 13f. The input signal terminal 13e receives the reset pulse (Reset2) output from the control circuit 11.

The delay circuit 42 is provided between the NOT circuit 131 and the gate terminal (G) of the N-channel MOSFET 133. The delay circuit 42 delays rising of the signal Ng input into the gate terminal (G) of the N-channel MOSFET 133 for a given period of time.

### (Configuration of Regenerative Circuit 41)

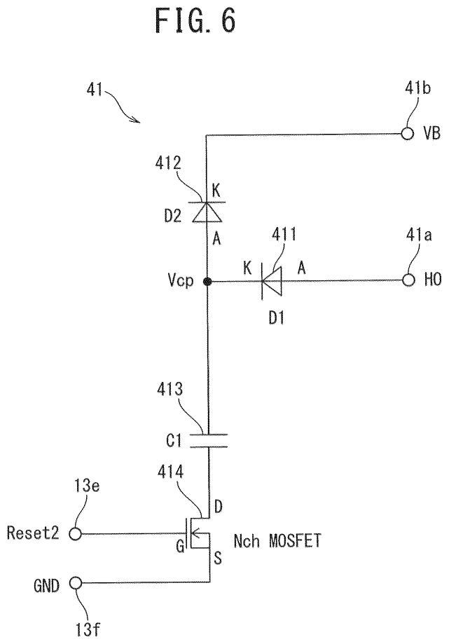

FIG. 6 is a circuit diagram illustrating a configuration of the regenerative circuit 41. The regenerative circuit 41 includes a diode 411 (an example of a first diode), a diode 412 (an example of a second diode), a capacitor 413, and an N-channel MOSFET 414 (an example of a third switching element).

The diode 411 includes an anode terminal (A) connected to the signal line SL1 via a signal terminal 41a, and a cathode terminal (K) connected to an anode terminal (A) of the diode 412. The diode 412 includes the anode terminal (A) connected to the cathode terminal (K) of the diode 411, and a cathode terminal (K) connected to the positive electrode of the driving power supply Vb via a positive terminal 41b.

A high-potential side of the capacitor 413 is connected to the cathode terminal (K) of the diode 411 and the anode terminal (A) of the diode 412, and a low-potential side thereof is connected to a drain terminal (D) of the N-channel MOSFET 414. A source terminal(S) of the N-channel MOSFET 414 is connected to a ground potential GND via the GND terminal 13f. A gate terminal (G) of the N-channel MOSFET 414 is connected to control circuit 11 via an input signal terminal 13e.

The N-channel MOSFET 414 is brought into a conductive state (the ON state) when the voltage of the reset pulse (Reset2) is equal to or more than a gate-source threshold voltage. When the N-channel MOSFET 414 is brought into the ON state, the potential of the capacitor 413 can be increased, and hereby, electric charges accumulated in the gate terminal (G) of the high-side power device 21 can be accumulated in the capacitor 413.

### (Operation of High-Side Driver Circuit 10A)

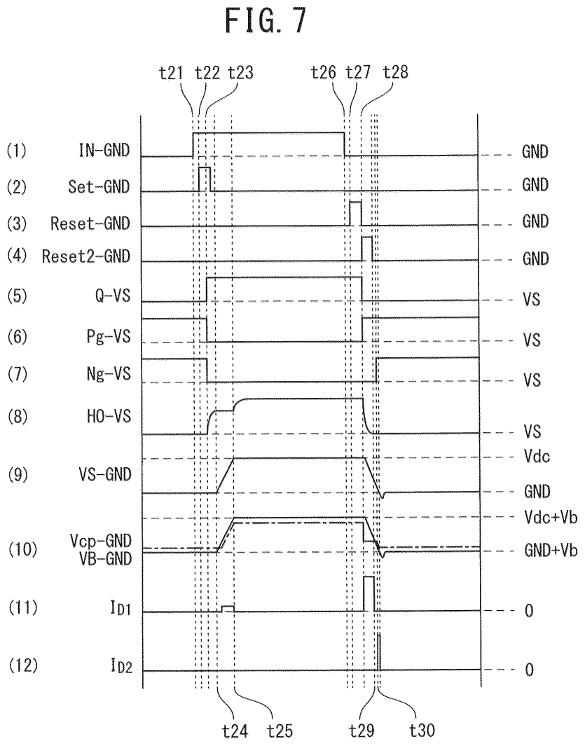

Next will be described an operation of the high-side driver circuit 10A according to the first embodiment with reference to FIG. 7 as well as FIGS. 1, 5, 6.

FIG. 7 is a signal timing diagram illustrating the operation of the high-side driver circuit 10A according to the first embodiment. In FIG. 7, the vertical axis indicates potential, and the horizontal axis indicates time. (1) in FIG. 7 indicates the waveform of the control signal (IN) input into the input signal terminal 15 of the high-side driver circuit 10A.

(2) in FIG. 7 indicates the waveform of a set pulse (Set) output from the control circuit 11. (3) in FIG. 7 indicates the waveform of a reset pulse (Reset) output from the control circuit 11. (4) in FIG. 7 indicates the waveform of a reset pulse (Reset2) output from the control circuit 11. (5) in FIG. 7 indicates the waveform of the signal Q of the high-side reference potential VS which signal Q is output from the level shift circuit 12. (6) in FIG. 7 indicates the waveform of the signal Pg input into the gate terminal (G) of the P-channel MOSFET 132. (7) in FIG. 7 indicates the waveform of the signal Ng input into the gate terminal (G) of the N-channel MOSFET 133. (8) in FIG. 7 indicates the waveform of the voltage HO of the gate terminal (G) of the high-side power device 21. (9) in FIG. 7 indicates the waveform of the high-side reference potential VS of the high-side power device 21.

(10) in FIG. 7 indicates the waveform of a high-potential side voltage Vcp of the capacitor 413 of the regenerative circuit 41 and the waveform of a voltage VB of the positive electrode of the driving power supply Vb. (11) in FIG. 7 indicates the waveform of a current ID1 flowing into the diode 411 of the regenerative circuit 41. (12) in FIG. 7 indicates the waveform of a current ID2 flowing into the diode 412 of the regenerative circuit 41.

In the high-side driver circuit 10A, in response to the control signal (IN) input into the input signal terminal 15 being switched from Low level to High level as indicated by (1) in FIG. 7 (time t21), the control circuit 11 outputs a set pulse (Set) indicated by (2) in FIG. 7 to the level shift circuit 12 (time t22).

Upon receipt of the set pulse (Set), the level shift circuit 12 switches the signal Q of the high-side reference potential VS from Low level to High level to output the driver circuit 13A as indicated by (5) in FIG. 7 (time t23). In the driver circuit 13A, the NOT circuit 131 reverses the signal Q of the high-side reference potential VS, outputs the signal (Pg) to the gate terminal (G) of the P-channel MOSFET 132, and outputs the signal (Ng) to the gate terminal (G) of the N-channel MOSFET 133. The signal (Pg) is indicated by (6) in FIG. 7. The signal (Ng) is indicated by (7) in FIG. 7.

When the P-channel MOSFET 132 is brought into the ON state and the N-channel MOSFET 133 is brought into the OFF state at time t23, a current output from the driving power supply Vb flows through the positive terminal 13b and the source terminal(S) and the drain terminal (D) of the P-channel MOSFET 132 and flows to a gate-emitter capacitance (not illustrated). The gate-emitter capacitance is formed between the gate terminal (G) and the emitter terminal (E) of the high-side power device 21. Hereby, the gate-emitter capacitance of the high-side power device 21 is charged, so that the gate voltage HO of the gate terminal (G) of the high-side power device 21 increases.

As a result, as indicated by (8) in FIG. 7, the gate voltage HO of the high-side power device 21 becomes higher than the high-side reference potential VS of the high-side power device 21 at time t24 at which a predetermined time elapses from time t23. After a mirror period (from time t24 to time t25), the gate voltage HO of the high-side power device 21 rises to a voltage value that can maintain the high-side power device 21 in the ON state (time t25). The mirror period corresponds to a predetermined time that elapses from time t24. That is, the high-side power device 21 is turned on. Note that, in the mirror period, the current output from the driving power supply Vb also flows through the diode 411 of the regenerative circuit 41 as indicated by (11) in FIG. 7.

In response to the high-side power device 21 being brought into the ON state, the high-side reference potential VS of the high-side power device 21 gradually rises from the ground potential GND to the potential of the direct-current power supply Vdc (from time t24 to time t25). The high-side reference potential VS is indicated by (9) in FIG. 7. The voltage VB (indicated by a solid line in FIG. 7) applied to the positive terminal 41b gradually rises from the potential of the driving power supply Vb to an addition potential (Vdc+Vb in FIG. 7) of the potential of the direct-current power supply Vdc and the potential of the driving power supply Vb (from time t24 to time t25). The voltage VB is indicated by (10) in FIG. 7. Since the current ID1 output from the diode 411 flows to the capacitor 413, the high-potential side voltage Vcp (indicated by an alternate long and short dash line in FIG. 7) of the capacitor 413 of the regenerative circuit 41 gradually rises (from time t24 to time t25).

In the meantime, in response to the control signal (IN) input into the input signal terminal 15 being switched from High level to Low level as indicated by (1) in FIG. 7 (time t26), the control circuit 11 outputs a reset pulse (Reset) to the level shift circuit 12 (time t27) and then outputs a reset pulse (Reset2) to the regenerative circuit 41 of the driver circuit 13A (time t28). The reset pulse (Reset) is indicated by (3) in FIG. 7. The reset pulse (Reset2) is indicated by (4) in FIG. 7.

Upon receipt of the reset pulse (Reset), the level shift circuit 12 switches the signal Q of the high-side reference potential VS from High level to Low level to output to the driver circuit 13A as indicated by (5) in FIG. 7 (time t28).

Since the P-channel MOSFET 132 is brought into the OFF state at time t28, the voltage level of the gate drive signal output from the output signal terminal 13c is Low level. Accordingly, electric charges accumulated in the gate-emitter capacitance of the high-side power device 21 are transferred to the diode 411 of the regenerative circuit 41 via the output signal terminal 13c and the signal line SL1, and are accumulated in the capacitor 413, so that the gate-emitter capacitance of the high-side power device 21 is discharged. Note that, since the N-channel MOSFET 133 is brought into the OFF state, electric charges accumulated in the gate-emitter capacitance of the high-side power device 21 do not transfer to the N-channel MOSFET 133 via the output signal terminal 13c and the signal line SL1. As a result, the gate voltage HO of the high-side power device 21 decreases, as indicated by (8) in FIG. 7. That is, the high-side power device 21 is turned off.

In order that the high-side power device 21 is turned off, the N-channel MOSFET 414 is turn on for a given period of time after the P-channel MOSFET 132 is turned off, so that electric charges (gate charges) accumulated in the gate-emitter capacitance of the high-side power device 21 are transferred to the capacitor 413 by the current I_{D1} flowed the diode 411 to extract gate charges, as indicated by (11) in FIG. 7.

In response to the high-side power device 21 being brought into the OFF state, the high-side reference potential VS of the high-side power device 21 gradually falls from the potential of the direct-current power supply Vdc to the ground potential GND (from time t28 to time t29). The high-side reference potential VS is indicated by (9) in FIG. 7. At the same time, the voltage VB gradually falls from the addition potential of the potential of the direct-current power supply Vdc and the potential of the driving power supply Vb to the potential of the driving power supply Vb (from time t28 time t29). The voltage VB is indicated by (10) of FIG. 7. In response to the voltage VB decreasing, the high-potential side voltage Vcp of the capacitor 413 becomes a high potential relative to the voltage VB (time t30). Accordingly, the diode 412 becomes conductive by the current I_{D2} indicated by (12) in FIG. 7, so that electric charges accumulated in the capacitor 413 are regenerated to the driving power supply Vb via the diode 412 and the positive terminal 17.

The signal (Ng) indicated by (7) in FIG. 7 is input into the delay circuit 42. After a delay time elapses after the signal (Ng) is input into the delay circuit 42, the delay circuit 42 output to the gate terminal (G) of the N-channel MOSFET 133 to turn on the N-channel MOSFET 133 (time t30), and hereby, the high-side power device 21 is fixed to the OFF state. The delay time is provided with the delay circuit 42. The delay time corresponds to a given period from turning off of the P-channel MOSFET 132 to turning off of the N-channel MOSFET 414.

That is, when the delay circuit 42 receives the signal (Ng) rising from Low level to High level, the delay circuit 42 outputs the signal (Ng) to the gate terminal (G) of the N-channel MOSFET 133 after the delay time elapses.

### Effects of First Embodiment

As described above, in the first embodiment, the capacitor 413 configured to accumulate gate charges of the high-side power device 21, the diode 411 that allows conduction only in a forward direction from the gate terminal (G) of the high-side power device 21 to the capacitor 413, the diode 412 that allows conduction only in the forward direction from the capacitor 413 to the driving power supply Vb, and the N-channel MOSFET 414 to be turned on only during a period in which gate charges are accumulated in the capacitor 413 are added to the conventional driver circuit B13.

This can accordingly reduce power consumption of the power conversion circuit 20. In addition, gate drive charges conventionally consumed as Joule heat are regenerated to the driving power supply Vb, and this can contribute to improving the efficiency of power consumption in a standby operation or the like that is a long-term operation with high carrier frequency and a small power conversion capacity of a main circuit.

### Second Embodiment

In the second embodiment of the present disclosure, it is preferable that a timing to turn on the N-channel MOSFET 133 be a timing when regeneration to the driving power supply Vb ends. In view of this, a signal corresponding to this timing is detected based on the high-potential side voltage Vcp of the capacitor 413 and a threshold voltage Vref, the N-channel MOSFET 133 is turned on with a delay time corresponding to a given period of time, and the high-side power device 21 is fixed to the OFF state.

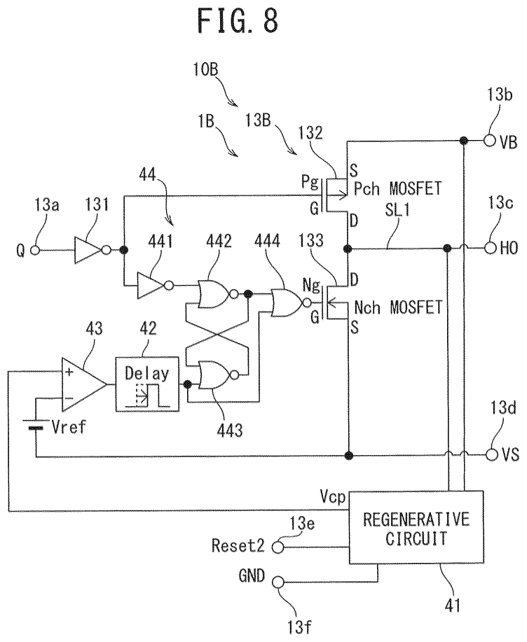

FIG. 8 is a circuit diagram illustrating a configuration of a driver circuit 13B of a semiconductor device 1B according to the second embodiment. In FIG. 8, the same portion as in FIG. 5 has the same reference sign as that of the portion in FIG. 5, and a detailed description thereof is omitted.

The driver circuit 13B includes the NOT circuit 131, the P-channel MOSFET 132 (an example of the first switching element), the N-channel MOSFET 133 (an example of the second switching element), the regenerative circuit 41, the delay circuit 42, a comparator 43 (an example of a delay control unit), a NOT circuit 441 constituting a signal holder 44, and NOR circuits 442, 443, 444.

The comparator 43 compares a voltage Vcp with the threshold voltage Vref based on the high-side reference potential VS, and controls an initiation timing of the delay circuit 42 based on a result of the comparison. The voltage Vcp is voltage Vcp of the cathode terminal (K) of the diode 411, that is, the voltage Vcp is high-potential side voltage Vcp of the capacitor 413.

An input end of the NOT circuit 441 is connected to the output end of the NOT circuit 131. An output end of the NOT circuit 441 is connected to one input end of the NOR circuit 442. An output end of the NOR circuit 443 is connected to the other input end of the NOR circuit 442. An output end of the NOR circuit 442 is connected to one input end of the NOR circuit 443 and one input end of the NOR circuit 444.

An output end of the delay circuit 42 is connected to the other input end of the NOR circuit 443. The output end of the delay circuit 42 is connected to the other input end of the NOR circuit 444. An output end of the NOR circuit 444 is connected to the gate terminal (G) of the N-channel MOSFET 133.

The signal holder 44 turns off the N-channel MOSFET 133 based on a Low-level signal output from the NOT circuit 131 while the high-side power device 21 is in the ON state. In response to the high-side power device 21 being brought into the OFF state, the signal holder 44 receives a High-level signal output from the NOT circuit 131 and maintains the N-channel MOSFET 133 in the OFF state until the signal holder 44 receives a delay signal from the delay circuit 42. Upon receipt of the delay signal from the delay circuit 42, the signal holder 44 turns on the N-channel MOSFET 133.

### (Operation of High-Side Driver Circuit 10B)

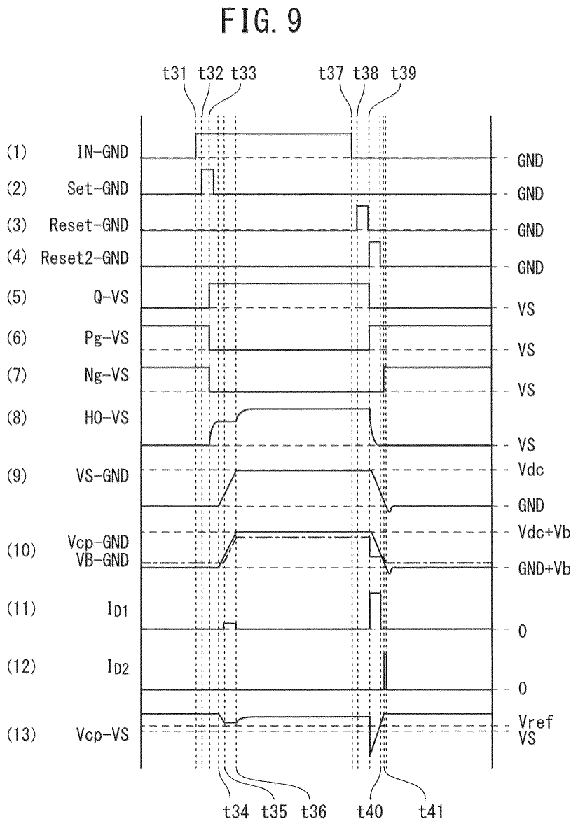

Next will be described an operation of a high-side driver circuit 10B according to the second embodiment with reference to FIG. 9 as well as FIG. 8.

FIG. 9 is a signal timing diagram illustrating an operation of the high-side driver circuit 10B according to the second embodiment. In FIG. 9, the vertical axis indicates potential, and the horizontal axis indicates time. (1) to (12) in FIG. 9 are the same as (1) to (12) in FIG. 7, and therefore, detailed descriptions are omitted. (13) in FIG. 9 indicates the high-potential side voltage Vcp of the capacitor 413 to be compared by the comparator 43 and the threshold voltage Vref based on the high-side reference potential VS.

In the high-side driver circuit 10A, in response to the control signal (IN) input into the input signal terminal 15 being switched from Low level to High level as indicated by (1) in FIG. 9 (time t31), the control circuit 11 outputs a set pulse (Set) indicated by (2) in FIG. 9 to the level shift circuit B12 (time t32). The set pulse (Set) is indicated by (2) in FIG. 9.

Upon receipt of the set pulse (Set), the level shift circuit 12 switches the signal Q of the high-side reference potential VS from Low level to High level to output the driver circuit 13B as indicated by (5) in FIG. 9 (time t33). In the driver circuit 13B, the NOT circuit 131 reverses the signal Q of the high-side reference potential VS, outputs the signal (Pg) to the gate terminal (G) of the P-channel MOSFET 132, and outputs the signal (Ng) to the gate terminal (G) of the N-channel MOSFET 133 via the signal holder 44. The signal (Pg) is indicated by (6) in FIG. 9. The signal (Ng) is indicated by (7) in FIG. 9.

When the P-channel MOSFET 132 is brought into the ON state and the N-channel MOSFET 133 is brought into the OFF state at time t33, a current output from the driving power supply Vb flows through the positive terminal 13b and the source terminal(S) and the drain terminal (D) of the P-channel MOSFET 132 and flows to a gate-emitter capacitance (not illustrated). The gate-emitter capacitance is formed between the gate terminal (G) and the emitter terminal (E) of the high-side power device 21. Hereby, the gate-emitter capacitance of the high-side power device 21 is charged, so that the gate voltage HO of the gate terminal (G) of the high-side power device 21 increases.

As a result, the gate voltage HO of the high-side power device 21 becomes higher than the high-side reference potential VS of the high-side power device 21 at time t34 at which a predetermined time elapses from time t33, as indicated by (8) in FIG. 9. After a mirror period (from time t34 to time t36), the gate voltage HO of the high-side power device 21 rises to a voltage value that can maintain the high-side power device 21 in the ON state (time t36). The mirror period corresponds to a predetermined time that elapses from time t34. That is, the high-side power device 21 is turned on. Note that, in the mirror period, the high-potential side voltage Vcp of the capacitor 413 as indicated by (13) in FIG. 9 falls down to the vicinity of the threshold voltage Vref (time t35), so that the current output from the driving power supply Vb also flows through the diode 411 of the regenerative circuit 41 as indicated by (11) in FIG. 9.

In response to the high-side power device 21 being brought into the ON state, the high-side reference potential VS of the high-side power device 21 gradually rises from the ground potential GND to the potential of the direct-current power supply Vdc (from time t34 to time t36). The high-side reference potential VS is indicated by (9) in FIG. 9. The voltage VB (indicated by a solid line in FIG. 9) applied to the positive terminal 41b gradually rises from the potential of the driving power supply Vb to an addition potential (Vdc+Vb in FIG. 9) of the potential of the direct-current power supply Vdc and the potential of the driving power supply Vb (from time t34 to time t36). The voltage VB is indicated by (10) in FIG. 9. Since the current ID1 output from the diode 411 flows to the capacitor 413, the high-potential side voltage Vcp of the capacitor 413 of the regenerative circuit 41 gradually rises (from time t34 to time t36). The voltage Vcp is indicated by an alternate long and short dash line in (10) in FIG. 9.

In the meantime, in response to the control signal (IN) input into the input signal terminal 15 being switched from High level to Low level as indicated by (1) in FIG. 9 (time t37), the control circuit 11 outputs a reset pulse (Reset) to the level shift circuit 12 (time t38) and then outputs a reset pulse (Reset2) to the regenerative circuit 41 of the driver circuit 13A (time t39). The reset pulse (Reset) is indicated by (3) in FIG. 9. The reset pulse (Reset2) is indicated by (4) in FIG. 9.

Upon receipt of the reset pulse (Reset), the level shift circuit 12 switches the signal Q of the high-side reference potential VS from High level to Low level to output to the driver circuit 13B as indicated by (5) in FIG. 9 (time t39).

Since the P-channel MOSFET 132 is brought into the OFF state at time t39, the voltage level of the gate drive signal output from the output signal terminal 13c is Low level. Accordingly, electric charges accumulated in the gate-emitter capacitance of the high-side power device 21 transfer to the diode 411 of the regenerative circuit 41 via the output signal terminal 13c and the signal line SL1 and are accumulated in the capacitor 413, so that the gate-emitter capacitance of the high-side power device 21 is discharged. Note that, since the N-channel MOSFET 133 is brought into the OFF state, electric charges accumulated in the gate-emitter capacitance of the high-side power device 21 do not flow to the N-channel MOSFET 133 via the output signal terminal 13c and the signal line SL1. As a result, the gate voltage HO of the high-side power device 21 decreases, as indicated by (8) in FIG. 9.

At the time when the high-side power device 21 is turned off, the N-channel MOSFET 414 is turn on for a given period of time after the P-channel MOSFET 132 is turned off, so that electric charges (gate charges) accumulated in the gate-emitter capacitance of the high-side power device 21 are transferred to the capacitor 413 by the current I_{D1} flowed the diode 411 as indicated by (11) in FIG. 9, and thus, gate charges are extracted. At this time, the high-potential side voltage Vcp of the capacitor 413 becomes lower than the high-side reference potential VS, as indicated by (13) in FIG. 9 (time t39).

In response to the high-side power device 21 being brought into the OFF state, the high-side reference potential VS of the high-side power device 21 gradually falls from the potential of the direct-current power supply Vdc to the ground potential GND (from time t39 to time t41). The high-side reference potential VS is indicated by (9) in FIG. 9. At the same time, the voltage VB gradually falls from the addition potential to the potential of the driving power supply Vb (from time t39 time t41). The voltage VB is indicated by (10) of FIG. 9. The addition potential is added the potential of the direct-current power supply Vdc and the potential of the driving power supply Vb. In response to the voltage VB decreasing, the high-potential side voltage Vcp of the capacitor 413 becomes a high potential relative to the voltage VB (time t41). Accordingly, the diode 412 becomes conductive by the current ID2 indicated by (12) in FIG. 9, so that electric charges accumulated in the capacitor 413 are regenerated to the driving power supply Vb via the diode 412 and the positive terminal 17.

At this time, the high-potential side voltage Vcp of the capacitor 413 becomes higher than the threshold voltage Vref, as indicated by (13) in FIG. 9 (time t41). In response to the high-potential side voltage Vcp of the capacitor 413 becoming higher than the threshold voltage Vref, the comparator 43 outputs a High-level signal to the delay circuit 42.

The delay circuit 42 outputs a delay signal to the signal holder 44 at a timing when the delay circuit 42 receives the High-level signal output from the comparator 43 and after a delay time elapses. Upon receipt of the delay signal from the delay circuit 42, the signal holder 44 outputs the High-level signal output by the NOT circuit 131 and held by the signal holder 44 to the gate terminal (G) of the N-channel MOSFET 133 and turns on the N-channel MOSFET 133.

### Effects of Second Embodiment

As described above, in the second embodiment, a timing when regeneration to the driving power supply Vb ends can be detected by the comparator 43 comparing the potential of the cathode of the diode 411, that is, the high-potential side voltage Vcp of the capacitor 413 with the threshold voltage Vref, and hereby, the timing to turn on the N-channel MOSFET 133 can be adjusted to the timing when the regeneration to the driving power supply Vb ends.

### OTHER EMBODIMENTS

The technical scope of the present disclosure is not limited to the exemplary embodiments illustrated and described herein and covers all embodiments that provide effects equivalent to those intended by the present disclosure. Further, the technical scope of the present disclosure is not limited to combinations of features of the disclosure defined by Claims but can be defined by any desired combination of specific features among the features disclosed herein.

What is claimed is:

1. A gate drive circuit for inputting a control signal to control a voltage-control switching element between ON state and OFF state, and for generating a driving signal to drive a voltage-control switching element based on the control signal, wherein the voltage-control switching element being configured to receive power from a direct-current power supply, the gate drive circuit comprising:
a signal line connected to a gate terminal of the voltage-control switching element;
a first switching element connected between a positive electrode of the direct-current power supply and the signal line;
a second switching element connected between a negative electrode of the direct-current power supply and the signal line; and
a regenerative circuit configured to accumulate electric charges in response to the voltage-control switching element being turned off, and regenerate the electric charges to the direct-current power supply, wherein the electric charges are accumulated in the gate terminal while the voltage-control switching element is turned on.

2. The gate drive circuit according to claim 1, wherein:
the regenerative circuit includes
a first diode including an anode connected to the signal line,
a second diode including an anode connected to a cathode of the first diode, and a cathode connected to the positive electrode of the direct-current power supply,
a capacitor in which a high-potential side is connected to the cathode of the first diode and the anode of the second diode, and
a third switching element connected between a low-potential side of the capacitor and a reference potential of the driving signal to the voltage-controlled switching element; and
the gate drive circuit further comprises
a control unit, and
a delay circuit configured to delay rising of a signal to be input into a gate terminal of the second switching element,
wherein the control unit configured to
control the first switching element to be brought into an ON state, and the second switching element and the third switching element to be brought into an OFF state, such that the driving signal is output from the first switching element to the gate terminal of the voltage-control switching element, in response to a control signal to turn on the first switching element, and,
control the first switching element to be brought into an OFF state and the second switching element and the third switching element to be brought into an ON state such that the output of the driving signal is stopped, in response to a control signal to turn off the first switching element.

3. The gate drive circuit according to claim 2, wherein
the control unit controls the third switching element to be brought into the ON state for only a predetermined setting time after an ON period of the voltage-control switching element ends, and the control unit transfers electric charges accumulated in the gate terminal of the voltage-control switching element to the capacitor.

4. The gate drive circuit according to claim 2, further comprising
a delay control unit configured to control a start timing to start the delay circuit to coincide with a timing when a potential of the cathode of the first diode exceeds a threshold voltage.
